(19) United States
(12) Patent Application Publication
(10) Pub. No.: US 2025/0359201 A1
(43) Pub. Date: Nov. 20, 2025

(54) SEMICONDUCTOR DEVICE

(71) Applicant: Renesas Electronics Corporation, Tokyo (JP)

(72) Inventors: Katsumi EIKYU, Tokyo (JP); Atsushi SAKAI, Tokyo (JP); Tomoya NISHIMURA, Tokyo (JP); Yasunori YAMASHITA, Tokyo (JP); Kenichi HISADA, Tokyo (JP)

(21) Appl. No.: 19/084,901

(22) Filed: Mar. 20, 2025

(30) Foreign Application Priority Data
May 17, 2024 (JP) 2024-081209

(51) Int. Cl. H10D 62/10; H10D 62/832; H10D 84/83

(52) U.S. Cl. CPC H10D 62/107; H10D 84/839; H10D 62/8325

(57) ABSTRACT

Provided is a wide band gap semiconductor device having high robustness against misalignment between gate electrodes (trenches) and a punch-through stopper layer. A technical concept is to configure the planar shape of the punch-through stopper layer from a pattern having periodicity in each of the X and Y directions constituting the plane, on the premise that the trenches extending in the Y direction out of the X direction and the Y direction constituting the plane are arranged at predetermined intervals in the X direction.

### CROSS-REFERENCE TO RELATED APPLICATIONS

The disclosure of Japanese Patent Application No. 2024-081209 filed on May 17, 2024 including the specification, drawings and abstract is incorporated herein by reference in its entirety.

### BACKGROUND

The present invention relates to a semiconductor device, and more particularly to a technique that is effective when applied to a semiconductor device that uses a wide band gap semiconductor material having a band gap larger than that of silicon.

There are disclosed techniques listed below. [Patent Document 1] Japanese Unexamined Patent Application Publication No. 2019-117859
Patent Document 1 discloses a technique for forming a semiconductor region of the opposite conductivity type to that of the drift layer in the drift layer deeper than a trench.

### SUMMARY

There is a semiconductor device that uses a wide band gap semiconductor material having a band gap larger than that of silicon in an epitaxial layer. In this wide band gap semiconductor device, the large band gap allows for a high breakdown voltage of the epitaxial layer, even when the thickness of the epitaxial layer is reduced. That is, the wide band gap semiconductor device can achieve both a reduction in the on-resistance and an improvement in breakdown voltage, which are in a trade-off relationship with each other.

Therefore, the wide band gap semiconductor device can achieve a higher operating voltage. However, for example, in a wide band gap semiconductor device including a field effect transistor having a structure in which a gate electrode is filled into a trench formed in an epitaxial layer via a gate insulating film, the electric field strength in the vicinity of the corners of the bottom of the trench increases as the operating voltage is increased. As a result, there is a risk of dielectric breakdown occurring in the gate insulating film formed in the trench.

For this reason, in a wide band gap semiconductor device, it is necessary to suppress the electric field concentration in the vicinity of the bottom of the trench. Accordingly, it has been considered to form a punch-through stopper layer of the opposite conductivity type to that of the epitaxial layer in the epitaxial layer deeper than the trench.

In this regard, the present inventors have newly discovered that misalignment between gate electrodes formed in trenches and a punch-through stopper layer formed in an epitaxial layer is a factor that causes variations in the characteristics of a wide band gap semiconductor device.

For this reason, there is a demand for a semiconductor device having high robustness against misalignment between the gate electrodes and the punch-through stopper layer.

Other objects and novel features will become apparent from the description of the present specification and the accompanying drawings.

According to one embodiment, a semiconductor device includes a punch-through stopper layer in which the planar shape thereof is configured of a pattern having periodicity in each of the X and Y directions constituting the plane, on the premise that the trenches extending in the Y direction out of the X direction and the Y direction constituting the plane are arranged at predetermined intervals in the X direction.

According to one embodiment, it is possible to provide a wide band gap semiconductor device having high robustness against misalignment between gate electrodes (trenches) and a punch-through stopper layer.

### BRIEF DESCRIPTION OF THE DRAWINGS

FIG. 1 is a diagram illustrating a configuration of a wide band gap semiconductor device including a MOSFET with a trench gate structure.

FIG. 2 is a diagram illustrating an example of forming a punch-through stopper layer.

FIG. 3 is a diagram illustrating an example of forming a punch-through stopper layer.

FIG. 4 is a diagram illustrating a planar positional relationship between a trench and punch-through stopper layers in the related art.

FIG. 5 is a diagram illustrating one shot in photolithography for forming a trench and a punch-through stopper layer.

FIG. 6 is a diagram for calculating δθ.

FIG. 7 is a diagram illustrating a semiconductor chip in a first embodiment.

FIG. 8 is an enlarged view of a cell block.

FIG. 9 is a diagram illustrating an example in which a relative misalignment δY occurs in the Y direction between the trenches and the punch-through stopper layer.

FIG. 10 is a diagram illustrating an example in which a relative misalignment δX occurs in the X direction between the trenches and the punch-through stopper layer.

FIG. 11 is a diagram illustrating a first modification of the first embodiment.

FIG. 12 is a diagram illustrating a second modification of the first embodiment.

FIG. 13 is a diagram illustrating a region of interest in a cell block in the second embodiment.

FIG. 14 is a diagram illustrating a configuration A of a pattern.

FIG. 15 is a diagram illustrating a configuration B of a pattern.

FIG. 16 is a diagram for explaining a third embodiment.

FIG. 17 is a diagram illustrating a process for implementing the configuration A of the third embodiment.

FIG. 18 is a diagram illustrating a process following FIG. 17.

FIG. 19 is a diagram illustrating a process following FIG. 18.

FIG. 20 is a diagram illustrating a process following FIG. 19.

FIG. 21 is a diagram illustrating a process for implementing the configuration B of the third embodiment.

FIG. 22 is a diagram illustrating a process following FIG. 21.

FIG. 23 is a diagram illustrating a process for implementing a configuration C of the third embodiment.

FIG. 24 is a diagram illustrating a process following FIG. 23.

FIG. 25 is a diagram illustrating a process following FIG. 24.

FIG. 26 is a diagram illustrating a process for implementing a configuration D of the third embodiment.

FIG. 27 is a diagram illustrating a process following FIG. 26.

FIG. 28 is a diagram illustrating a process following FIG. 27.

FIG. 29 is a diagram illustrating a process following FIG. 28.

### DETAILED DESCRIPTION

In all the drawings for explaining the embodiments, the same members are generally given the same reference numerals, and repeated explanations thereof will be omitted. For clarity in the drawings, hatching may be applied even in plan views.

A semiconductor device having an epitaxial layer mainly made of a wide band gap semiconductor material having a band gap larger than that of silicon (hereinafter referred to as a wide band gap semiconductor device) has been attracting attention. This is because a large band gap indicates high dielectric breakdown strength, facilitating the achievement of high breakdown voltage more easily.

Furthermore, if the semiconductor material itself has high dielectric breakdown strength, the breakdown voltage can be secured even if the epitaxial layer (also referred to as a drift layer) that maintains the breakdown voltage is made thin. Accordingly, for example, by thinning the epitaxial layer and increasing the impurity concentration, the on-resistance of the wide band gap semiconductor device can be reduced.

That is, the wide band gap semiconductor device is advantageous in that both an improvement in breakdown voltage and a reduction in on-resistance, which are in a trade-off relationship with each other can be achieved. Therefore, a wide band gap semiconductor device is expected to be a promising semiconductor device capable of achieving high performance.

Examples of semiconductor materials with a band gap larger than that of silicon include silicon carbide (SiC), gallium nitride (GaN), gallium oxide (Ga₂O₃), diamond, etc. The following description focuses on silicon carbide.

### <Background of Considerations>

### <<Usefulness of Punch-Through Stopper Layer>>

For example, a wide band gap semiconductor device includes a field effect transistor (hereinafter sometimes referred to as MOSFET) having a trench gate structure in which a gate electrode is filled into a trench formed in an epitaxial layer on a semiconductor substrate via a gate insulating film.

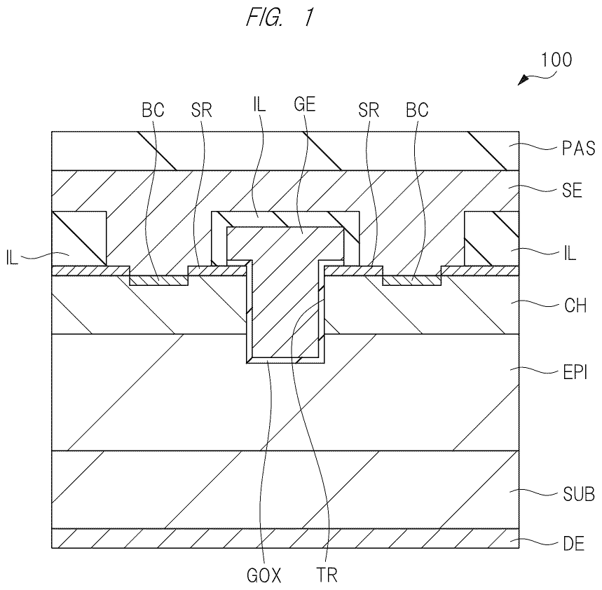

FIG. 1 is a diagram illustrating a configuration of a wide band gap semiconductor device 100 including a MOSFET with a trench gate structure. As illustrated in FIG. 1, the wide band gap semiconductor device 100 includes a drain electrode DE, a semiconductor substrate SUB, an epitaxial layer EPI, a trench TR, a gate insulating film GOX, a gate electrode GE, a source region SR, a body contact region BC, a channel layer CH, an insulating layer IL, a source electrode SE, and a surface protective film PAS.

The semiconductor substrate SUB, the epitaxial layer EPI, and the source region SR are made of n-type semiconductor regions. Meanwhile, the body contact region BC and the channel layer CH are made of p-type semiconductor regions.

To turn on the MOSFET, a gate voltage equal to or higher than a threshold voltage is applied to the gate electrode GE. As a result, a channel made of an inversion layer (n-type semiconductor region) is formed in the channel layer CH in contact with the side surface of the trench TR. Accordingly, a current flows along the path from the drain electrode DE, the semiconductor substrate SUB, the epitaxial layer EPI, the channel (inversion layer), the source region SR, and to the source electrode SE. The MOSFET is turned on in this manner.

To turn off the MOSFET, a gate voltage lower than the threshold voltage is applied to the gate electrode GE. As a result, the channel made of the inversion layer formed in the channel layer CH in contact with the side surface of the trench TR disappears. Accordingly, the current path between the drain electrode DE and the source electrode SE is cutoff. The MOSFET is turned off in this manner.

When the MOSFET is in an off state, for example, “0 V” is applied to the source electrode SE, the source region SR, the body contact region BC, and the channel layer CH. On the other hand, a positive potential (several hundred V to several thousand V) is applied to the drain electrode DE, the semiconductor substrate SUB, and the epitaxial layer EPI. As a result, a reverse bias is applied to the pn junction between the channel layer CH (p-type semiconductor region) and the epitaxial layer EPI (n-type semiconductor region). Due to this, a depletion layer extends from the pn junction into the channel layer CH and from the pn junction into the epitaxial layer EPI. In the depletion layer, an electric field is generated in response to a source-drain voltage applied between the source electrode SE and the drain electrode DE. In particular, in the wide band gap semiconductor device 100, the source-drain voltage becomes high. This increases the electric field strength in the depletion layer. Accordingly, for example, the electric field strength increases in the vicinity of the bottom of the trench TR in the depletion layer extending in the epitaxial layer EPI in FIG. 1. This may cause a dielectric breakdown of the gate insulating film GOX formed in the trench TR.

Therefore, in order to suppress the electric field concentration in the vicinity of the bottom of the trench TR, it has been considered to form a punch-through stopper layer (p-type semiconductor region) of the opposite conductivity type to that of the epitaxial layer EPI in the epitaxial layer EPI deeper than the trench TR.

In this case, in the region where the punch-through stopper layer is arranged, the voltage applied to the drain is mainly applied to the pn junction formed by the punch-through stopper layer and the epitaxial layer EPI, therefore, depletion is suppressed in the pn junction formed by the channel layer CH and the epitaxial layer EPI above. Similarly, the electric field rise at the bottom of the trench TR is also suppressed. Accordingly, by forming the punch-through stopper layer in the epitaxial layer EPI, the dielectric breakdown of the gate insulating film GOX formed in the trench TR is suppressed.

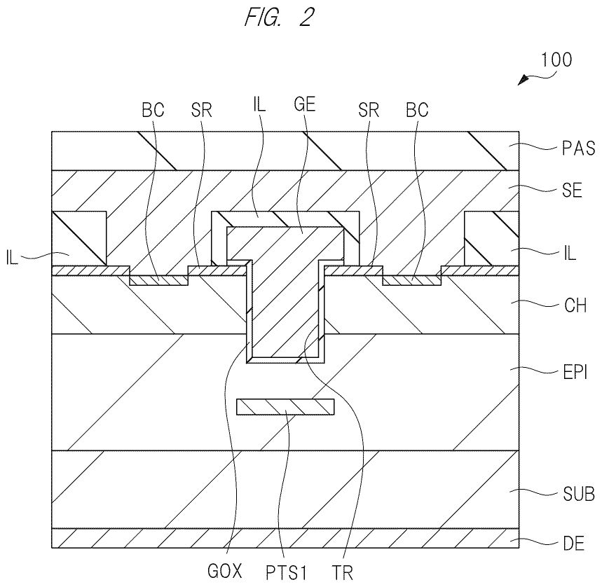

FIG. 2 is a diagram illustrating an example of forming a punch-through stopper layer PTS1.

In FIG. 2, the punch-through stopper layer PTS1 is formed in the epitaxial layer EPI below the trench TR. In this case, a rise in the electric field strength in the vicinity of the bottom of the trench TR can be effectively suppressed. On the other hand, if the punch-through stopper layer PTS1 is formed at the position illustrated in FIG. 2, the current path of the MOSFET is blocked. Therefore, when the punch-through stopper layer PTS1 is formed in the epitaxial layer EPI below the trench TR, the electric field concentration in the vicinity of the bottom of the trench TR can be efficiently alleviated, while the on-resistance of the MOSFET increases.

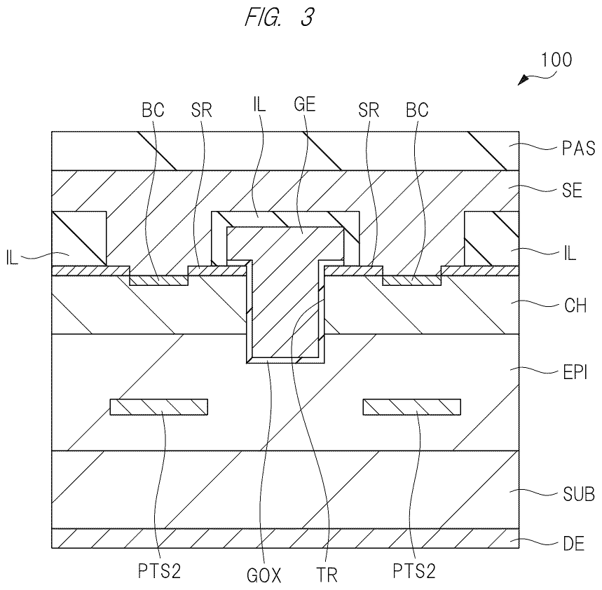

FIG. 3 is a diagram illustrating an example of forming a punch-through stopper layer PTS2.

In FIG. 3, the punch-through stopper layer PTS2 is formed in the epitaxial layer EPI away from below the trench TR. In other words, in cross-sectional view, the punch-through stopper layer PTS2 is formed at a position not overlapping with the trench TR. In this case, since the punch-through stopper layer PTS2 is unlikely to block the current path of the MOSFET, an increase in the on-resistance of the MOSFET caused by providing the punch-through stopper layer PTS2 can be suppressed. On the other hand, the effect of suppressing a rise in the electric field strength in the vicinity of the bottom of the trench TR is smaller than that of the punch-through stopper layer PTS1 illustrated in FIG. 2.

Therefore, the following related art is being considered regarding the punch-through stopper layer.

### DESCRIPTION OF RELATED ART

In the present specification, the term “related art” refers to a technique that is not publicly known, but involves issues identified by the inventors and serves as a premise for the present disclosure.

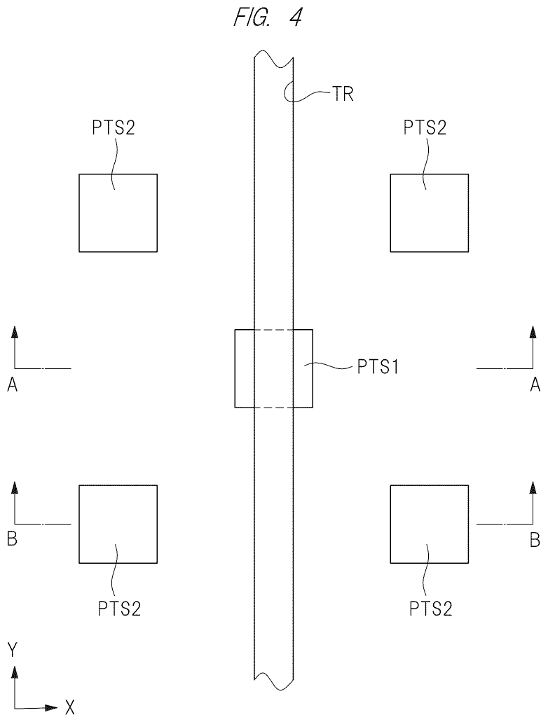

FIG. 4 is a diagram illustrating a planar positional relationship between the trench TR and the punch-through stopper layers in the related art. In FIG. 4, the punch-through stopper layer in the related art is configured of the punch-through stopper layer PTS1 illustrated in FIG. 2 and the punch-through stopper layer PTS2 illustrated in FIG. 3. That is, the A-A cross section of FIG. 4 corresponds to FIG. 2, and the B-B cross section of FIG. 4 corresponds to FIG. 3. Thus, the related art includes the punch-through stopper layer PTS1 and the punch-through stopper layer PTS2. The punch-through stopper layer PTS1 is formed below the trench TR. Meanwhile, in plan view, the punch-through stopper layer PTS2 is formed at a position not overlapping with the trench TR.

According to the related art, this configuration reduces the on-resistance of the MOSFET more than when the whole punch-through stopper layer is formed from the punch-through stopper layer PTS1. Moreover, according to the related art, the configuration alleviates the electric field concentration in the vicinity of the bottom of the trench TR more efficiently than when the whole punch-through stopper layer is formed from the punch-through stopper layer PTS2.

Therefore, the related art can achieve both alleviation of the electric field concentration in the vicinity of the bottom of the trench TR and a reduction in the on-resistance of the MOSFET.

### <<Considerations of Improvements in Related Art>>

However, the present inventors have newly discovered that misalignment between gate electrodes formed in trenches and a punch-through stopper layer formed in an epitaxial layer is a factor that causes variations in the characteristics of a wide band gap semiconductor device.

For example, in FIG. 4, if the formation positions of the punch-through stopper layer PTS1 and the punch-through stopper layer PTS2 are misaligned in the X direction, the relative positional relationship between the trenches TR and the punch-through stopper layer PTS1 and the relative positional relationship between the trenches TR and the punch-through stopper layer PTS2 change. As a result, variations in the characteristics of the wide band gap semiconductor device occur. That is, the related art has room for improvement in terms of securing robustness against misalignment between the gate electrodes formed in the trenches and the punch-through stopper layer formed in the epitaxial layer. Accordingly, there is a demand for a wide band gap semiconductor device having high robustness against misalignment between the gate electrodes (trenches) and the punch-through stopper layer. In other words, a technical concept for overcoming the room for improvement existing in the related art is desired.

### <Components of Misalignment>

First, before describing the technical concept, a description will be given of components of misalignment that should be taken into consideration as the misalignment between the trenches and the punch-through stopper layer.

For example, when an XY plane is taken into consideration, independent components of the misalignment between the trenches and the punch-through stopper layer are misalignment δX in the X direction, misalignment δY in the Y direction, and misalignment δθ in the θ direction. Accordingly, in order to implement a wide band gap semiconductor device that has high robustness against misalignment between the trenches and the punch-through stopper layer, it is crucial to find a planar shape of the punch-through stopper layer that can reduce the change in the relative positional relationship between the trenches and the punch-through stopper layer caused by δX, δY, and δθ.

In this regard, it will be described that δθ can be ignored.

FIG. 5 is a diagram illustrating one shot ST in photolithography for forming the trenches and the punch-through stopper layer. In FIG. 5, the exposure area, one shot ST, is, for example, 1000 μm×1000 μm in size. The exposure area includes an alignment mark AM1 and an alignment mark AM2. The alignment mark AM1 and the alignment mark AM2 serve to align the trenches with the punch-through stopper layer. Misalignment between the alignment mark AM1 and the alignment mark AM2 generates δX, δY, and δθ. The following provides an estimation of δθ.

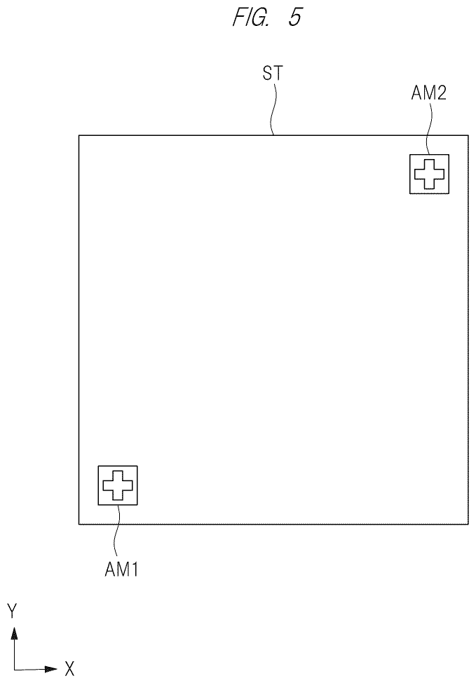

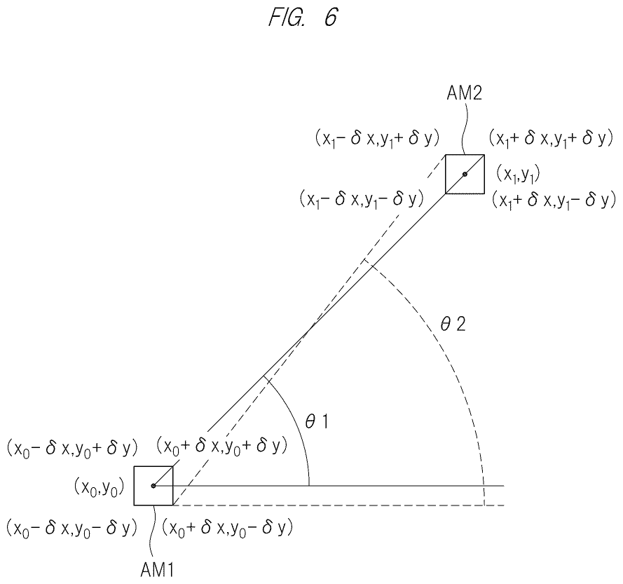

FIG. 6 is a diagram used to calculate δθ. As illustrated in FIG. 6, the position coordinates of the alignment mark AM1 and the position coordinates of the alignment mark AM2 are defined. In this case, θ1 is expressed by the following formula 1. Also, θ2 is expressed by the following formula 2.

$$[ Expression 1 ]$$

$$θ 1 = {cos}^{- 1} ( \frac{\vert {x}_{1} - {x}_{0} \vert}{\sqrt{{( {x}_{1} - {x}_{0} )}^{2} + {( {y}_{1} - {y}_{0} )}^{2}}} ) \qquad ( Formula 1 )$$

$$[ Expression 2 ]$$

$$θ 2 = {cos}^{- 1} ( \frac{\vert {x}_{1} - {x}_{0} - 2 δ x \vert}{{( {x}_{1} - {x}_{0} - 2 δ x )}^{2} + {( {y}_{1} - {y}_{0} + 2 δ y )}^{2}} ) \qquad ( Formula 2 )$$

Here, δθ=θ2−θ1. For example, assuming the size of one shot to be 1000 μm×1000 μm, δθ<0.0010 is obtained, indicating that δθ is an extremely small value. From this, δθ can be ignored.

From the above, when the XY plane is taken into consideration, the independent components of the misalignment between the trenches and the punch-through stopper layer that cannot be ignored are δX and δY. Accordingly, δθ can be ignored, therefore, in order to implement a wide band gap semiconductor device that has high robustness against misalignment between the trenches and the punch-through stopper layer, it only needs to find a planar shape of the punch-through stopper layer that can reduce the change in the relative positional relationship between the trenches and the punch-through stopper layer caused by δX and δY.

Therefore, hereinafter, a technical concept regarding the planar shape of the punch-through stopper layer that can reduce the change in the relative positional relationship between the trenches and the punch-through stopper layer caused by 5X and 5Y will be described.

### <Basic Concept>

A basic concept is to configure the planar shape of the punch-through stopper layer from a pattern having periodicity in each of the X and Y directions constituting the plane, on the premise that the trenches extending in the Y direction out of the X direction and the Y direction constituting the plane are arranged at predetermined intervals in the X direction. Accordingly, even if a relative misalignment occurs between the trenches and the punch-through stopper layer, the change in the relative positional relationship between the trenches and the punch-through stopper layer caused by the misalignment can be reduced when viewed over the entire chip. As a result, according to the basic concept, variations in the characteristics of the wide band gap semiconductor device can be suppressed. That is, according to the basic concept, it is possible to provide a wide band gap semiconductor device having high robustness against misalignment between the trenches and the punch-through stopper layer.

For example, the punch-through stopper layer is divided into a plurality of portions in plan view. Each of the plurality of portions is the same size as the others. There are portions that are adjacent to each other within the plurality of portions. The basic concept is that a first pattern, where the planar shapes of each adjacent portion are identical to each other, is formed in each of the adjacent portions. The first pattern is formed of one or more sub-patterns. Here, in plan view, the one or more sub-patterns forming the first pattern each partially overlap with any of a plurality of gate electrodes (a plurality of trenches).

Accordingly, on the premise that the trenches and the punch-through stopper layer have portions that overlap in plan view, the planar shape of the punch-through stopper layer is configured of a pattern having periodicity in each of the X direction and the Y direction constituting the plane.

For example, the planar shape of the punch-through stopper layer forms a geometric pattern composed of repetitions of the above-mentioned first pattern as a unit pattern.

In the present specification, the term “geometric pattern” is defined as a certain type of pattern, and specifically has the following meaning. Specifically, a “geometric pattern” refers to a pattern created by combining and arranging simple figures as components, such as polygons (e.g., triangles, squares, and hexagons), circles, ellipses, and straight lines, with those geometric components undergoing operations such as translation, inversion, and rotation. A “geometric pattern” allows for infinite pattern expansion through the repetition of the same operations. Additionally, a “geometric pattern” can also be described as a figure generated by geometric curves that can be expressed using periodic functions.

In consideration of the above, the first pattern is configured of one or more sub-patterns including any of straight lines, rectangles, circles, and curves. In particular, the first pattern is configured of a pattern capable of tessellating a plane. Here, the “pattern capable of tessellating a plane” referred to in the present specification is a pattern that uses a finite number of planar figures, where the adjacent planar figures do not overlap, and the adjacent planar figures can fill the plane without any gaps. It should be noted that this does not exclude the provision of an opening inside the planar figures.

For example, the first pattern is configured of a pattern capable of tessellating a plane. In this case, the first pattern is configured of a plurality of sub-patterns, and the plurality of sub-patterns is configured of a combination of a plurality of single figures. In this case, the single figure is a triangle, a square, or a hexagon. Also, the first pattern can also be configured of a pattern capable of tessellating a plane using a combination of a plurality of types of figures, rather than the combination of a plurality of single figures described above. Specifically, the first pattern is configured of a plurality of sub-patterns, and the plurality of sub-patterns is configured of a combination of a plurality of types of figures.

The basic concept is based on the premise that the trenches extending in the Y direction out of the X direction and Y direction constituting the plane are arranged at predetermined intervals in the X direction. Moreover, the basic concept is on the premise that the trenches and the punch-through stopper layer have portions that partially overlap each other in plan view. As a specific example of a precondition, the following configuration can be given. That is, each of the plurality of gate electrodes extends in a first direction (Y direction), and, in plan view, each of one or more sub-patterns configuring the first pattern extends in a second direction (X direction) that intersects the first direction. This satisfies the precondition.

In the punch-through stopper layer, each of a first portion and a second portion of the punch-through stopper layer has not only the first pattern, but also may have a second pattern having a ring shape surrounding the first pattern in plan view. The first pattern is, for example, connected to the second pattern. The second pattern is supplied with the ground potential. Therefore, the configuration of the punch-through stopper layers in the basic concept includes an aspect in which the ground potential is supplied.

In the following, a first embodiment will be described below as an example that embodies the basic concept.

### First Embodiment

### <<Configuration of Wide Band Gap Semiconductor Device>>

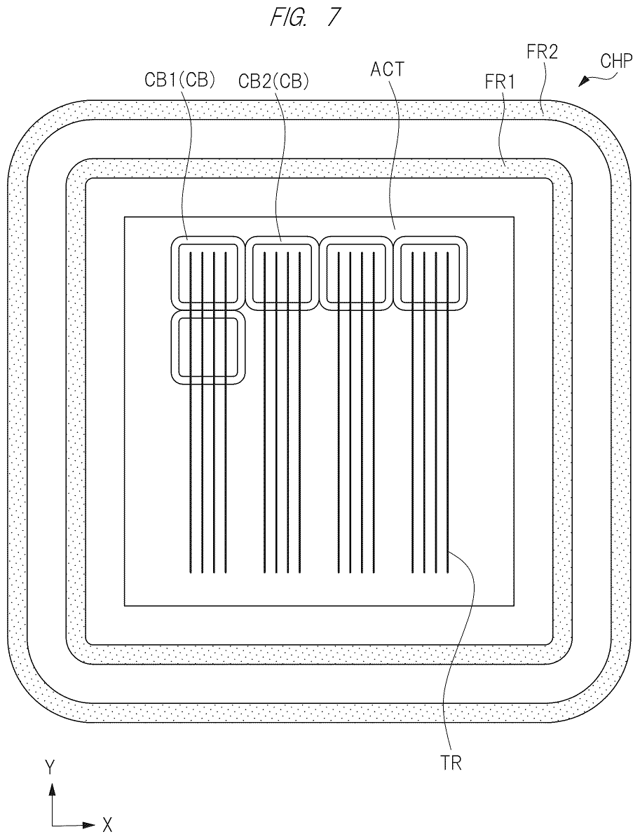

FIG. 7 is a diagram illustrating a semiconductor chip CHP in a first embodiment.

In FIG. 7, the semiconductor chip CHP includes an active region ACT, a floating ring FR1, and a floating ring FR2. The active region ACT is a region in which semiconductor elements such as MOSFETs are formed. The floating ring FR1 is formed so as to surround the active region ACT in plan view. Also, the floating ring FR2 is formed so as to surround the floating ring FR1 in plan view. The floating ring FR1 and the floating ring FR2 are provided to secure the insulation breakdown voltage of the semiconductor chip CHP.

The active region ACT includes a plurality of trenches TR. Each of the plurality of trenches TR extends in the Y direction. The plurality of trenches TR is formed so as to be aligned in the X direction at predetermined intervals. In the first embodiment, the active region ACT has a plurality of cell blocks CB. For example, as illustrated in FIG. 7, the plurality of cell blocks CB includes a cell block CB1 and a cell block CB2 that are adjacent to each other. The cell block CB1 is a region in which a first portion of the punch-through stopper layer is formed. Also, the cell block CB2 is a region in which a second portion of the punch-through stopper layer is formed.

The cell block CB1 and the cell block CB2 are the same size. The cell block CB1 and the cell block CB2 adjacent to each other have first patterns formed therein, the first patterns having the same planar shape. The configuration of the cell block CB in which the first pattern is formed will be described below.

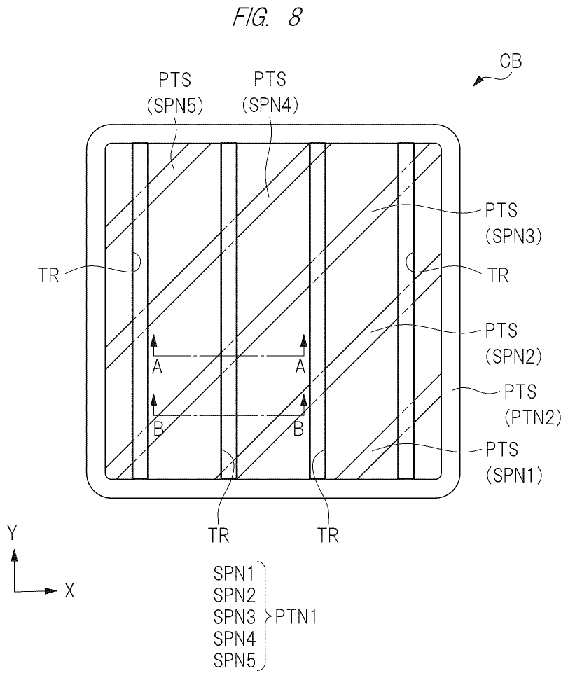

FIG. 8 is an enlarged view of the cell block CB. In FIG. 8, the cell block CB includes the trenches TR, a pattern PTN1 and a pattern PTN2.

The trenches TR extend in the Y direction and are arranged so as to aligned at predetermined intervals in the X direction. FIG. 8 illustrates four trenches TR aligned at predetermined intervals in the X direction.

The pattern PTN1 is configured of one or more sub-patterns. For example, in FIG. 8, the pattern PTN1 is configured of a sub-pattern SPN1, a sub-pattern SPN2, a sub-pattern SPN3, a sub-pattern SPN4 and a sub-pattern SPN5. That is, the pattern PTN1 illustrated in FIG. 8 is configured of five sub-patterns. Each of the sub-pattern SPN1, the sub-pattern SPN2, the sub-pattern SPN3, the sub-pattern SPN4 and the sub-pattern SPN5 is a pattern of the punch-through stopper layer PTS. Therefore, the pattern PTN1 configures a combination of patterns of the punch-through stopper layer PTS. For example, in FIG. 8, the pattern PTN1 is configured of five sub-patterns, each of which is configured of a diagonal straight line.

Each of the sub-pattern SPN1, the sub-pattern SPN2, the sub-pattern SPN3, the sub-pattern SPN4 and the sub-pattern SPN5 configuring the pattern PTN1 partially overlaps with any one of the plurality of trenches TR (four trenches TR in FIG. 8). In other words, when the gate electrodes being formed inside the trenches TR is taken into consideration, each of the sub-pattern SPN1, the sub-pattern SPN2, the sub-pattern SPN3, the sub-pattern SPN4 and the sub-pattern SPN5 partially overlaps with any of the plurality of gate electrodes (four gate electrodes in FIG. 8). Specifically, in FIG. 8, each of the plurality of trenches TR (plurality of gate electrodes) extends in the Y direction, and in plan view, each of the five sub-patterns configuring the pattern PTN1 extends in the X direction that intersects with the Y direction.

The pattern PTN2 has a ring shape surrounding the pattern PTN1 in plan view. That is, the pattern PTN2 has a ring shape surrounding the five sub-patterns configuring the pattern PTN1 in plan view. The pattern PTN2 is connected to the pattern PN1. That is, the planar shape of the punch-through stopper layer PTS is configured of a combination of the pattern PTN1 including the five sub-patterns and the pattern PTN2 having a ring shape surrounding the pattern PTN1 in plan view.

The cross-sectional view taken along line A-A in FIG. 8 is substantially the same as FIG. 2. Also, the cross-sectional view taken along line B-B in FIG. 8 is substantially the same as FIG. 3. It should be noted that the punch-through stopper layer PTS1 in FIG. 2 corresponds the punch-through stopper layer PTS in the cross-sectional view taken along the line A-A in FIG. 8. Also, the punch-through stopper layer PTS2 in FIG. 3 corresponds the punch-through stopper layer PTS in the cross-sectional view taken along the line B-B in FIG. 8.

The wide band gap semiconductor device in the first embodiment includes a drain electrode DE, a semiconductor substrate SUB, an epitaxial layer EPI, trenches TR, a gate insulating film GOX, gate electrodes GE, a source region SR, a body contact region BC, a channel layer CH, a punch-through stopper layer PTS, an insulating layer IL, a source electrode SE and a surface protective film PAS.

The semiconductor substrate SUB is made of, for example, silicon carbide doped with n-type impurities (donors). The drain electrode DE is formed on the lower surface of the semiconductor substrate SUB. Meanwhile, the epitaxial layer EPI is formed on the upper surface of the semiconductor substrate SUB. The epitaxial layer EPI is an n-type semiconductor layer made of silicon carbide.

The channel layer CH is a p-type semiconductor layer formed in the epitaxial layer EPI. The trenches TR are formed so as to penetrate the channel layer CH and reach the inside of the epitaxial layer EPI. The gate insulating film GOX is formed on the inner walls of the trenches TR. The gate electrodes GE are filled in the trenches TR via the gate insulating film GOX.

The punch-through stopper layer PTS is formed in the epitaxial layer EPI. The punch-through stopper layer PTS is a p-type semiconductor layer formed at a position deeper than the trenches TR. The source region SR is an n-type semiconductor region formed in the channel layer CH. The source region SR is in contact with the trenches TR. Also, the body contact region BC is a p-type semiconductor region formed in the channel layer CH. The impurity concentration of the body contact region BC is higher than the impurity concentration of the channel layer CH.

The source electrode SE is formed on the insulating layer IL and in a contact hole penetrating the insulating layer IL. The source electrode SE is electrically connected to the source region SR and the body contact region BC. Therefore, the source region SR and the body contact region BC are electrically connected to each other via the source electrode SE. The surface protective film PAS is formed on the source electrode SE. The wide band gap semiconductor device according to the first embodiment is configured as described above.

### <<Features of First Embodiment>>

Next, features of the first embodiment will be described.

A feature of the first embodiment is based on the premise that, as illustrated in FIG. 7, for example, a plurality of cell blocks CB has the same size in plan view. Also, a feature is based on the premise that the pattern PTN1 is formed in each of the plurality of cell blocks CB that has the same planar shape. Under such premises, for example, as illustrated in FIG. 8, the pattern PTN1 is configured of a plurality of sub-patterns. In FIG. 8, the plurality of sub-patterns includes a sub-pattern SPN1, a sub-pattern SPN2, a sub-pattern SPN3, a sub-pattern SPN4 and a sub-pattern SPN5. And, each of the plurality of sub-patterns configuring the pattern PTN1 partially overlaps any of the plurality of trenches TR in plan view. Thus, a feature is that the planar shape of the punch-through stopper layer PTS configures the pattern PTN1 having the above-mentioned configuration.

As a result, according to the first embodiment, it is based on the premise that the trenches TR and the punch-through stopper layer PTS have partially overlapping portions in plan view, the planar shape of the punch-through stopper layer PTS can be configured of a pattern having periodicity in each of the X direction and the Y direction constituting the plane. As a result, according to the first embodiment, even if a relative misalignment (δX or δY) occurs between the trenches TR and the punch-through stopper layer PTS, when viewed over the entire chip, the change in the relative positional relationship between the trenches TR and the punch-through stopper layer PTS caused by the misalignment can be reduced. As a result, according to the features, variations in the characteristics of the wide band gap semiconductor device can be suppressed. That is, according to the features, it is possible to provide a wide band gap semiconductor device having high robustness against misalignment between the trenches TR and the punch-through stopper layer PTS.

The details will be described below.

In FIG. 8, there is no relative misalignment between the trenches TR and the punch-through stopper layer PTS. In FIG. 8, there is a portion in the cell block CB that corresponds to the positional relationship between the trench TR and the punch-through stopper layer PTS illustrated in the A-A cross section (FIG. 2). FIG. 8 also illustrates a portion corresponding to the positional relationship between the trenches TR and the punch-through stopper layer PTS illustrated in the B-B cross section (FIG. 3).

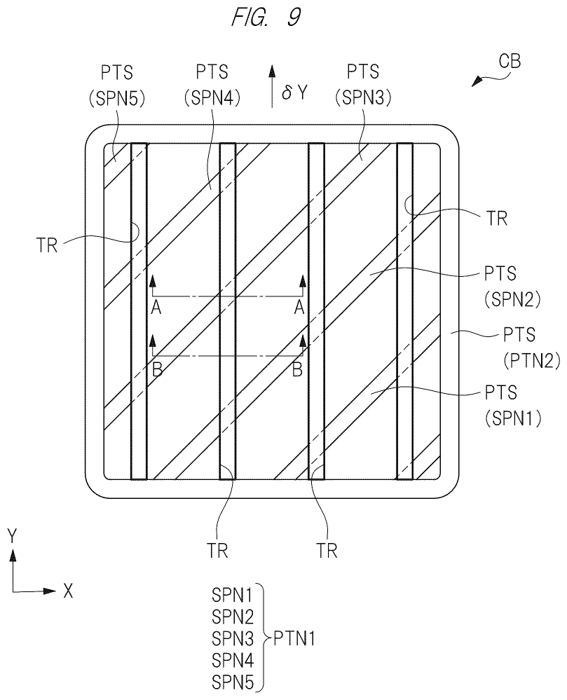

FIG. 9 is a diagram illustrating an example in which a relative misalignment δY occurs in the Y direction between the trenches TR and the punch-through stopper layer PTS. Also in FIG. 9, there is a portion in the cell block CB that corresponds to the positional relationship between the trench TR and the punch-through stopper layer PTS illustrated in the A-A cross section (FIG. 2). FIG. 9 also illustrates a portion corresponding to the positional relationship between the trenches TR and the punch-through stopper layer PTS illustrated in the B-B cross section (FIG. 3).

FIG. 10 is a diagram illustrating an example in which a relative misalignment 5X occurs in the X direction between the trenches TR and the punch-through stopper layer PTS. Also in FIG. 10, there is a portion in the cell block CB that corresponds to the positional relationship between the trench TR and the punch-through stopper layer PTS illustrated in the A-A cross section (FIG. 2). FIG. 10 also illustrates a portion corresponding to the positional relationship between the trenches TR and the punch-through stopper layer PTS illustrated in the B-B cross section (FIG. 3).

Considering FIGS. 8, 9, and 10, even if a relative misalignment (δX or δY) occurs between the trenches TR and the punch-through stopper layer PTS, in the cell block CB, there are a position that corresponds to the positional relationship between the trench TR and the punch-through stopper layer PTS illustrated in the A-A cross section (FIG. 2), and a portion that corresponds to the positional relationship between the trenches TR and the punch-through stopper layer PTS illustrated in the B-B cross section (FIG. 3). This means that, when viewed over the entire chip, the change in the relative positional relationship between the trenches TR and the punch-through stopper layer PTS caused by the misalignment can be reduced. As a result, according to the first embodiment, variations in the characteristics of the wide band gap semiconductor device can be suppressed. That is, according to the first embodiment, it is possible to provide a wide band gap semiconductor device having high robustness against misalignment between the trenches TR and the punch-through stopper layer PTS.

### First Modification of First Embodiment

FIG. 11 is a diagram illustrating a first modification of the first embodiment.

In FIG. 11, the planar shape of the punch-through stopper layer PTS configures a pattern PTN1. In the first modification, the pattern PTN1 is configured of a sub-pattern SPN1, a sub-pattern SPN2, a sub-pattern SPN3, a sub-pattern SPN4, a sub-pattern SPN5. a sub-pattern SPN6, a sub-pattern SPN7, a sub-pattern SPN8, a sub-pattern SPN9 and a sub-pattern SPN10.

In the first modification configured in this manner, it is based on the premise that the trenches TR and the punch-through stopper layer PTS have partially overlapping portions in plan view, the planar shape of the punch-through stopper layer PTS can be configured of a pattern having periodicity in each of the X direction and the Y direction constituting the plane. As a result, also in the first modification, even if a relative misalignment (5X or 5Y) occurs between the trenches TR and the punch-through stopper layer PTS, when viewed over the entire chip, the change in the relative positional relationship between the trenches TR and the punch-through stopper layer PTS caused by the misalignment can be reduced. As a result, according to the first modification, variations in the characteristics of the wide band gap semiconductor device can also be suppressed. That is, according to the first modification, it is possible to provide a wide band gap semiconductor device having high robustness against misalignment between the trenches TR and the punch-through stopper layer PTS.

### Second Modification of First Embodiment

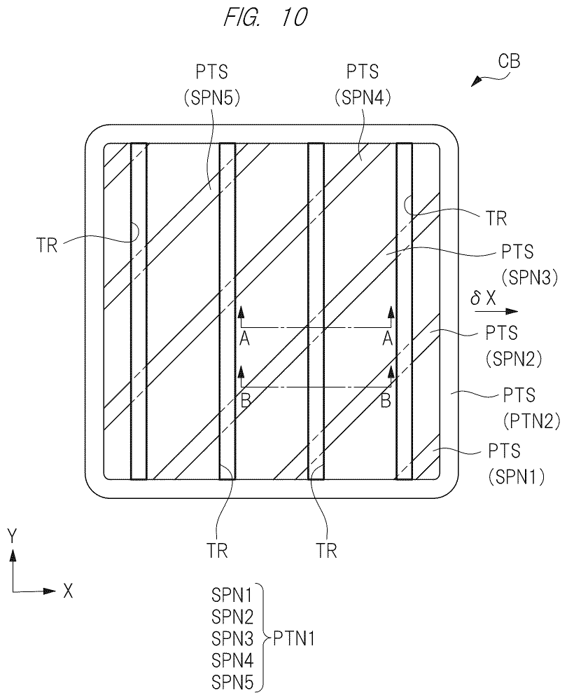

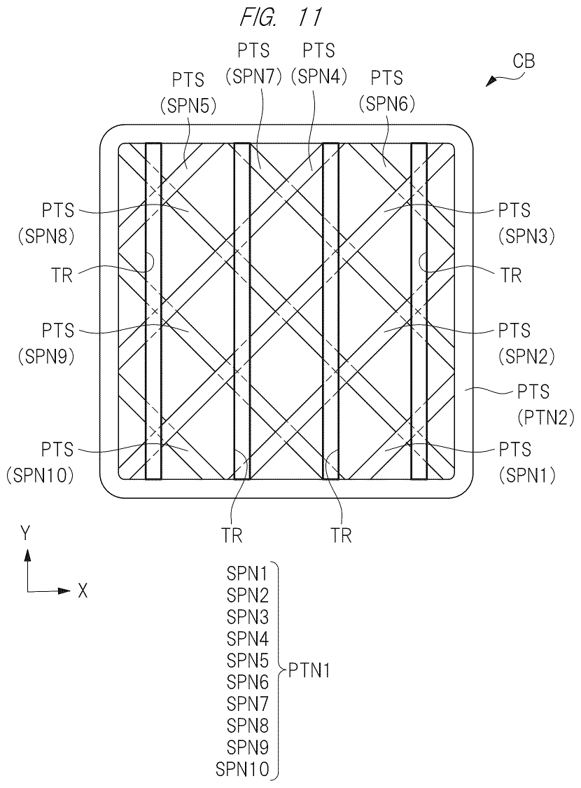

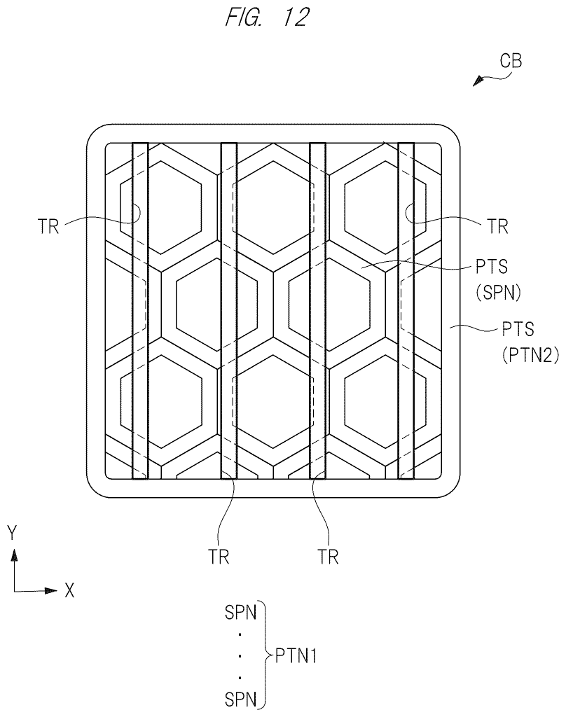

FIG. 12 is a diagram illustrating a second modification of the first embodiment.

In FIG. 12, the planar shape of the punch-through stopper layer PTS configures a pattern PTN1. In the second modification, the first pattern PTN1 is configured of a plurality of sub-patterns SPN, and the plurality of sub-patterns is configured of a combination of a plurality of single figures. That is, a sub-pattern SPN has a hexagonal shape (single figure), and the plurality of sub-patterns SPN configures a “pattern capable of tessellating a plane”.

In the second modification configured in this manner, it is based on the premise that the trenches TR and the punch-through stopper layer PTS have partially overlapping portions in plan view, the planar shape of the punch-through stopper layer PTS can be configured of a pattern having periodicity in each of the X direction and the Y direction constituting the plane. As a result, also in the second modification, even if a relative misalignment (δX or δY) occurs between the trenches TR and the punch-through stopper layer PTS, when viewed over the entire chip, the change in the relative positional relationship between the trenches TR and the punch-through stopper layer PTS caused by the misalignment can be reduced. As a result, according to the second modification, variations in the characteristics of the wide band gap semiconductor device can also be suppressed. That is, according to the second modification, it is possible to provide a wide band gap semiconductor device having high robustness against misalignment between the trenches TR and the punch-through stopper layer PTS.

### Second Embodiment

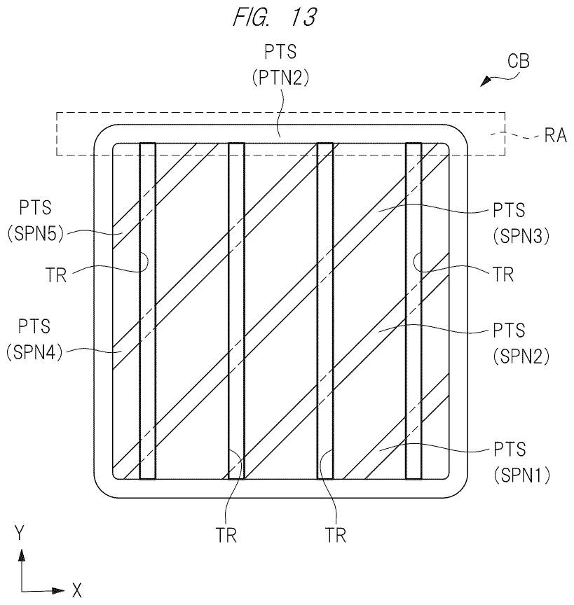

FIG. 13 is a diagram illustrating a region RA of interest in the outermost cell block CB in the second embodiment. In the second embodiment, the configuration of a pattern PTN2 in the region RA will be described. The configuration of the pattern PTN2 may be either a configuration A or a configuration B illustrated below.

### Configuration A of Second Embodiment

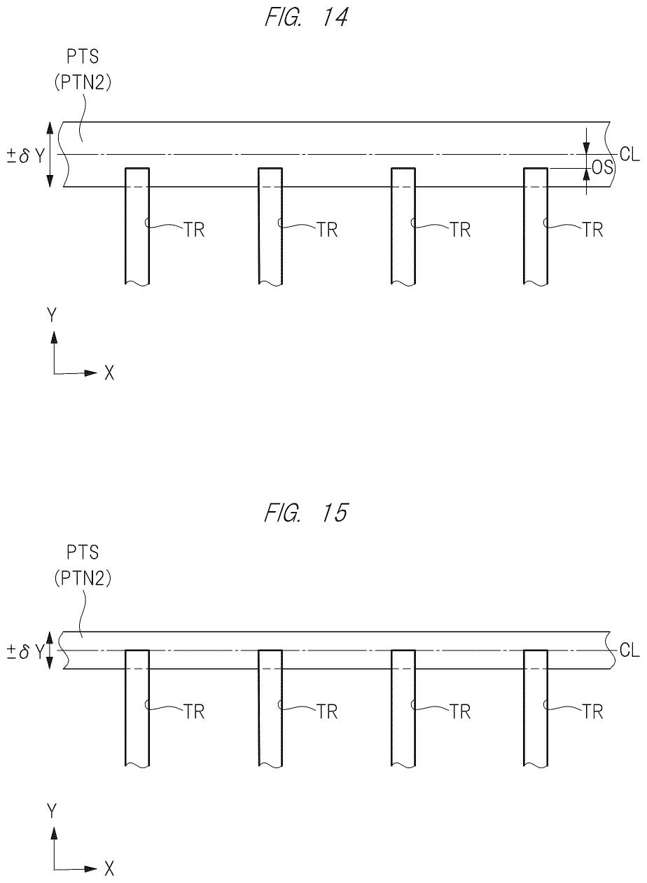

FIG. 14 is a diagram illustrating the configuration A of the pattern PTN2. As illustrated in FIG. 14, in the configuration A, an offset OS is provided between a center line CL in the Y direction of the pattern PTN2 extending in the X direction and the trenches TR. As a result, according to the configuration A, a sufficient margin can be secured for misalignment ±δY in the Y direction between the trenches TR and the pattern PTN2 (punch-through stopper layer).

### Configuration B of Second Embodiment

FIG. 15 is a diagram illustrating the configuration B of the pattern PTN2. As illustrated in FIG. 15, in the configuration B, the offset OS is not provided between the center line CL in the Y direction of the pattern PTN2 extending in the X direction and the trenches TR. This allows the chip size to be reduced.

### Third Embodiment

For example, in the related art illustrated in FIG. 4, the potential of the punch-through stopper layer PTS1 and the potential of the punch-through stopper layer PTS2 are set to a floating potential. In this case, when the MOSFET is repeatedly switched, a temporary potential shift occurs due to the accumulation of holes, particularly in the punch-through stopper layer PTS1. As a result, the dynamic characteristics of a wide band gap semiconductor device including a MOSFET are adversely affected.

To cope with this, it is conceivable to fix the potential of the punch-through stopper layer to the ground potential (OV). Accordingly, the potential of the punch-through stopper layer is fixed to the ground potential, so that even if the switching operation of the MOSFET is repeated, a potential shift in the punch-through stopper layer can be suppressed. As a result, the effect on the dynamic characteristics of a wide band gap semiconductor device including a MOSFET is reduced.

In this regard, for example, in FIG. 8 illustrating the first embodiment, the planar shape of the punch-through stopper layer PTS is configured of the pattern PTN1 including the plurality of sub-patterns SPN1 to SPN5, and the pattern PTN2 having a ring shape and surrounding the pattern PTN1. If a configuration can be implemented in which the ground potential is supplied to the punch-through stopper layer PTS configured in this manner, the punch-through stopper layer PTS can be fixed to the ground potential.

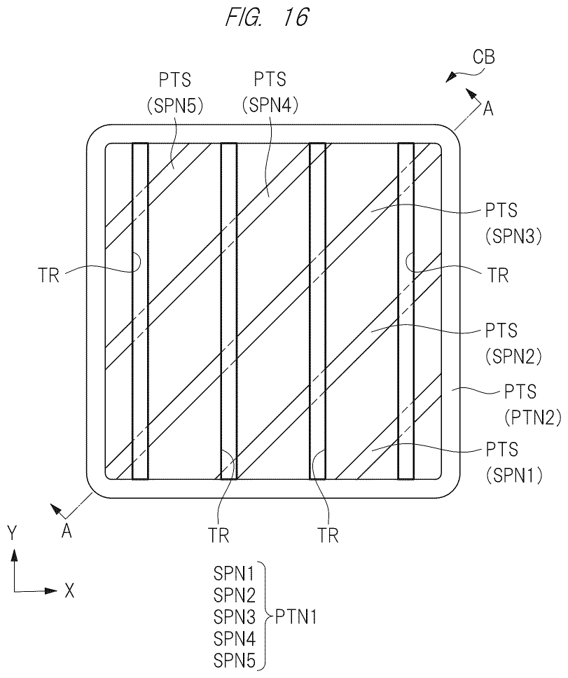

A configuration example in which the ground potential is supplied to the punch-through stopper layer PTS will be described below. A specific description will be given with reference to a manufacturing process diagram of the A-A cross section in FIG. 16.

### Configuration A of Third Embodiment

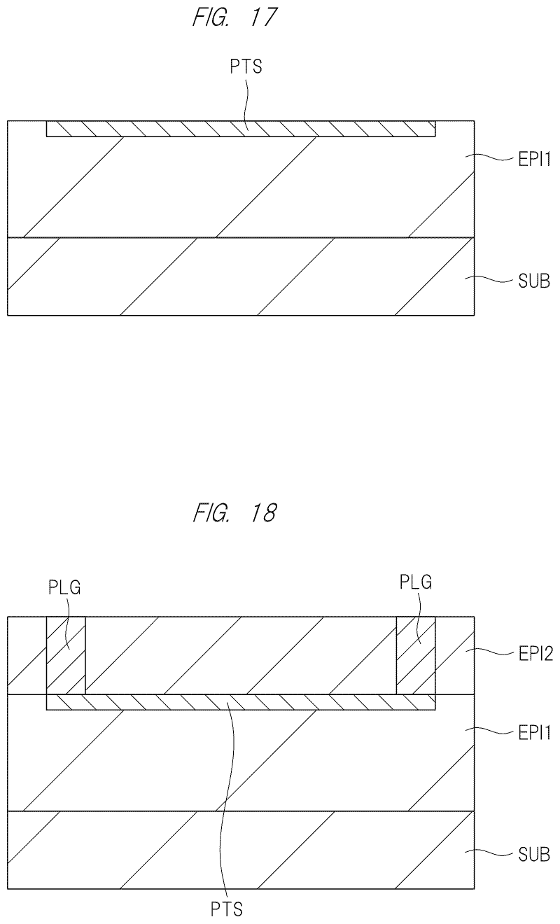

First, as illustrated in FIG. 17, an epitaxial layer EPI1 is formed on an n-type semiconductor substrate SUB by using epitaxial growth. Next, aluminum, which is p-type impurities (acceptor), is introduced into the epitaxial layer EPI1 by using photolithography and ion implantation. Accordingly, the punch-through stopper layer PTS is formed in the epitaxial layer EPI1.

Subsequently, as illustrated in FIG. 18, an epitaxial layer EPI2 is formed by epitaxial growth on the epitaxial layer EPI1 in which the punch-through stopper layer PTS is formed. Thereafter, p-type plugs PLG are formed in the epitaxial layer EPI2 by using photolithography and ion implantation. The p-type plugs PLG are connected to the punch-through stopper layer PTS.

Thereafter, as illustrated in FIG. 19, p-type impurities are introduced into the epitaxial layer EPI2 by using photolithography and ion implantation to form a channel layer CH. Then, by using photolithography and ion implantation, n-type impurities are introduced into the channel layer CH to form a source region SR.

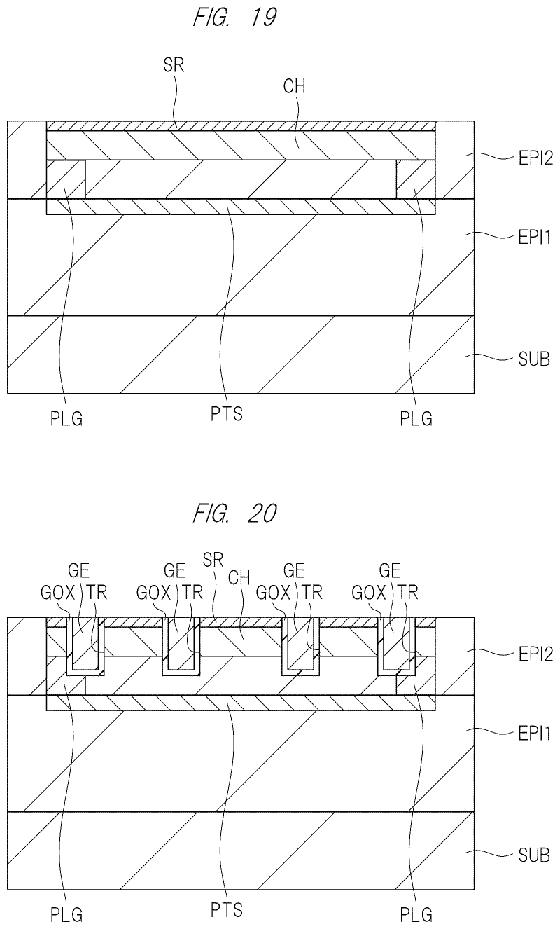

Next, as illustrated in FIG. 20, trenches TR are formed by using photolithography and etching. Then, after forming a gate insulating film GOX on the inner walls of the trenches TR, gate electrodes GE are formed in the trenches TR via the gate insulating film GOX. In this manner, the epitaxial layer EPI1, the punch-through stopper layer PTS, the epitaxial layer EPI2, the p-type plugs PLG, the channel layer CH, the source region SR, the trenches TR, the gate insulating film GOX, and the gate electrodes GE can be formed.

Here, the source region SR and the channel layer CH are electrically connected to each other and supplied with the ground potential. That is, the ground potential is supplied to each of the source region SR and the channel layer CH. The punch-through stopper layer PTS is electrically connected to the channel layer CH to which the ground potential is supplied via the p-type plugs PLG. Therefore, the ground potential is supplied to the punch-through stopper layer PTS. In this manner, the configuration in which the ground potential is supplied to the punch-through stopper layer PTS can be implemented.

The advantage of manufacturing such a structure A is that the p-type plugs PLG can be formed by a single high-energy ion implantation. Accordingly, the manufacturing process can be simplified.

### Configuration B of Third Embodiment

First, as illustrated in FIG. 17, an epitaxial layer EPI1 is formed on an n-type semiconductor substrate SUB by using epitaxial growth. Next, aluminum, which is p-type impurities (acceptor), is introduced into the epitaxial layer EPI1 by using photolithography and ion implantation. Accordingly, the punch-through stopper layer PTS is formed in the epitaxial layer EPI1.

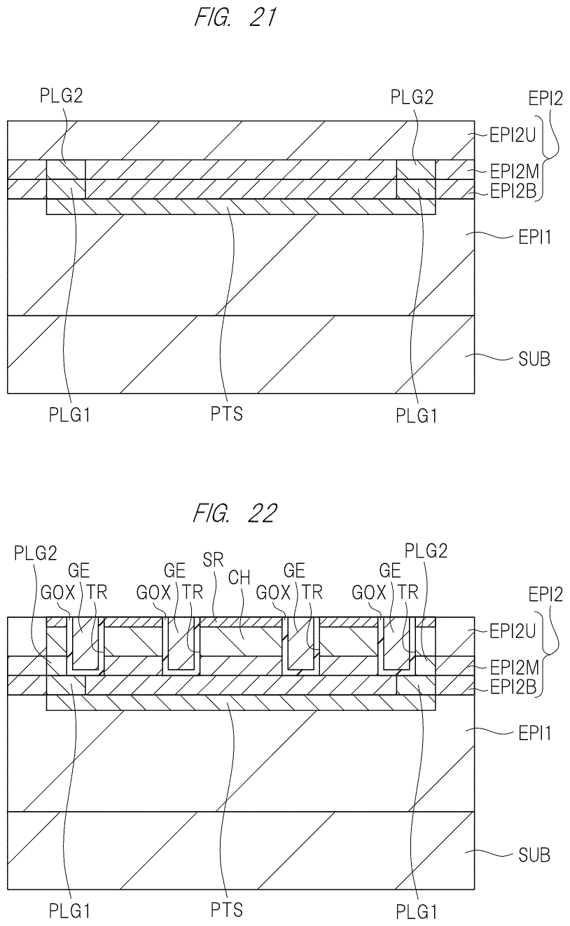

Subsequently, as illustrated in FIG. 21, a lower epitaxial layer EPI2B in which a punch-through stopper layer PTS is formed is formed. By using photolithography and ion implantation, p-type plugs PLG1 (lower plugs) are formed in the lower epitaxial layer EPI2B. The p-type plugs PLG1 are connected to the punch-through stopper layer PTS.

Next, a middle epitaxial layer EPI2M is formed on the lower epitaxial layer EPI2B in which the p-type plugs PLG1 are formed. By using photolithography and ion implantation, p-type plugs PLG2 (middle plugs) are formed in the middle epitaxial layer EPI2M. The p-type plugs PLG2 are connected to the p-type plugs PLG1. Next, an upper epitaxial layer EPI2U is formed on the middle epitaxial layer EPI2M in which the p-type plugs PLG2 are formed. The lower epitaxial layer EPI2B, the middle epitaxial layer EPI2M, and the upper epitaxial layer EPI2U configure the epitaxial layer EPI2.

Thereafter, as illustrated in FIG. 22, p-type impurities are introduced into the upper epitaxial layer EPI2U by using photolithography and ion implantation to form a channel layer CH. Then, by using photolithography and ion implantation, n-type impurities are introduced into the channel layer CH to form a source region SR.

Next, trenches TR are formed by using photolithography and etching. Then, after forming a gate insulating film GOX on the inner walls of the trenches TR, gate electrodes GE are formed in the trenches TR via the gate insulating film GOX. In this manner, the epitaxial layer EPI1, the punch-through stopper layer PTS, the lower epitaxial layer EPI2B, the middle epitaxial layer EPI2M, the upper epitaxial layer EPI2U, the p-type plugs PLG1, the p-type plug PLG2, the channel layer CH, the source region SR, the trenches TR, the gate insulating film GOX, and the gate electrodes GE can be formed.

The source region SR and the channel layer CH are electrically connected to each other and supplied with the ground potential. That is, the ground potential is supplied to each of the source region SR and the channel layer CH. The punch-through stopper layer PTS is electrically connected to the channel layer CH to which the ground potential is supplied via the p-type plugs PLG1 and the p-type plugs PLG2. Therefore, the ground potential is supplied to the punch-through stopper layer PTS. In this manner, the configuration in which the ground potential is supplied to the punch-through stopper layer PTS can be implemented.

The advantage of manufacturing such a structure B is that the p-type plugs PLG1 and the p-type plugs PLG2 can be formed by low-energy ion implantation.

### Configuration C of Third Embodiment

First, as illustrated in FIG. 17, an epitaxial layer EPI1 is formed on an n-type semiconductor substrate SUB by using epitaxial growth. Next, aluminum, which is p-type impurities (acceptor), is introduced into the epitaxial layer EPI1 by using photolithography and ion implantation. Accordingly, the punch-through stopper layer PTS is formed in the epitaxial layer EPI1.

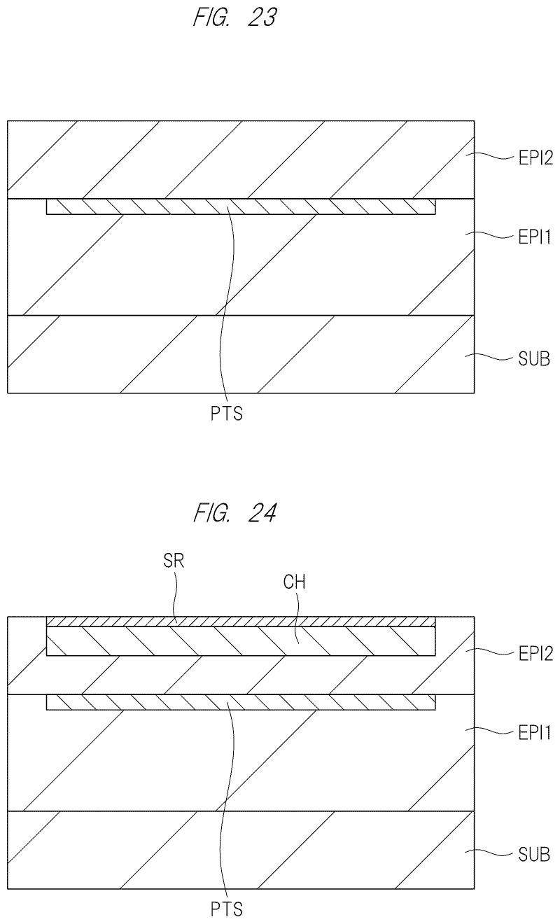

Subsequently, as illustrated in FIG. 23, an epitaxial layer EPI2 is formed by epitaxial growth on the epitaxial layer EPI1 in which the punch-through stopper layer PTS is formed. Thereafter, as illustrated in FIG. 24, p-type impurities are introduced into the epitaxial layer EPI2 by using photolithography and ion implantation to form a channel layer CH. Then, by using photolithography and ion implantation, n-type impurities are introduced into the channel layer CH to form a source region SR.

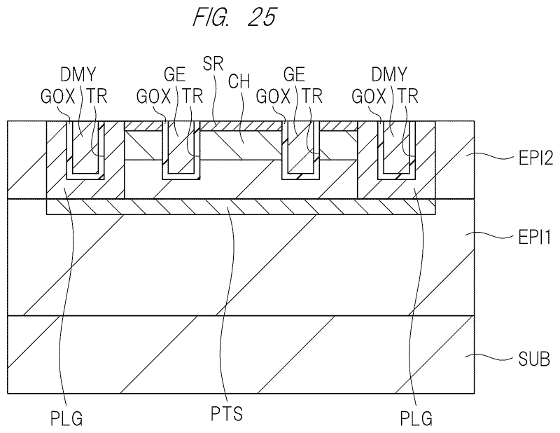

Next, as illustrated in FIG. 25, trenches TR are formed by using photolithography and etching. Then, after forming a gate insulating film GOX on the inner walls of the trenches TR, gate electrodes GE and dummy electrodes DMY that do not function as a gate electrode are formed in the trenches TR via the gate insulating film GOX. Thereafter, by using photolithography and oblique ion implantation, p-type plugs PLG containing the dummy electrodes DMY are formed. The p-type plugs PLG are connected to the punch-through stopper layer PTS. In this manner, the epitaxial layer EPI1, the punch-through stopper layer PTS, the epitaxial layer EPI2, the p-type plugs PLG, the channel layer CH, the source region SR, the trenches TR, the gate insulating film GOX, the gate electrodes GE, and the dummy electrodes DMY can be formed.

The source region SR and the channel layer CH are electrically connected to each other and supplied with the ground potential. That is, the ground potential is supplied to each of the source region SR and the channel layer CH. The punch-through stopper layer PTS is electrically connected to the channel layer CH to which the ground potential is supplied via the p-type plugs PLG. Therefore, the ground potential is supplied to the punch-through stopper layer PTS. In this manner, the configuration in which the ground potential is supplied to the punch-through stopper layer PTS can be implemented.

The advantage of manufacturing such a structure C is that, by using oblique ion implantation, the p-type plugs PLG can be formed by low-energy ion implantation.

### Configuration D of Third Embodiment

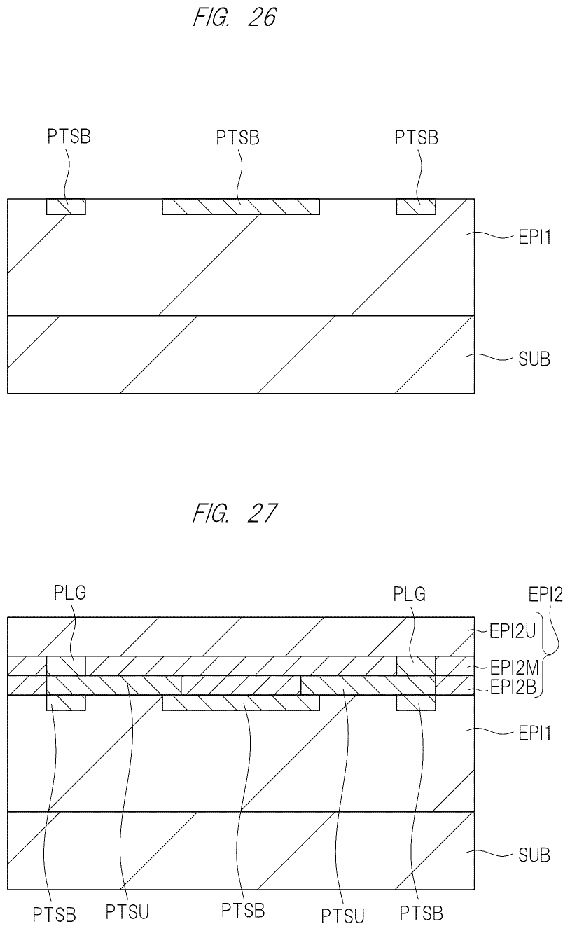

First, as illustrated in FIG. 26, an epitaxial layer EPI1 is formed on an n-type semiconductor substrate SUB by using epitaxial growth. Next, aluminum, which is p-type impurities (acceptor), is introduced into the epitaxial layer EPI1 by using photolithography and ion implantation. Accordingly, the punch-through stopper layer PTSB is formed in the epitaxial layer EPI1.

Subsequently, as illustrated in FIG. 27, a lower epitaxial layer EPI2B is formed on the epitaxial layer EPI1 in which the punch-through stopper layer PTSB is formed. Next, aluminum, which is p-type impurities (acceptor), is introduced into the lower epitaxial layer EPI2B by using photolithography and ion implantation. Accordingly, the punch-through stopper layer PTSU is formed in the lower epitaxial layer EPI2B. The punch-through stopper layer PTSU is connected to the punch-through stopper layer PTSB.

Thereafter, a middle epitaxial layer EPI2M is formed on the lower epitaxial layer EPI2B in which the punch-through stopper layer PTSU is formed. By using photolithography and ion implantation, p-type plugs PLG are formed in the middle epitaxial layer EPI2M. The p-type plugs PLG are connected to the punch-through stopper layer PTSU. An upper epitaxial layer EPI2U is formed on the middle epitaxial layer EPI2M in which the p-type plugs PLG are formed. The lower epitaxial layer EPI2B, the middle epitaxial layer EPI2M, and the upper epitaxial layer EPI2U configure the epitaxial layer EPI2.

Thereafter, as illustrated in FIG. 28, p-type impurities are introduced into the upper epitaxial layer EPI2U by using photolithography and ion implantation to form a channel layer CH. Then, by using photolithography and ion implantation, n-type impurities are introduced into the channel layer CH to form a source region SR.

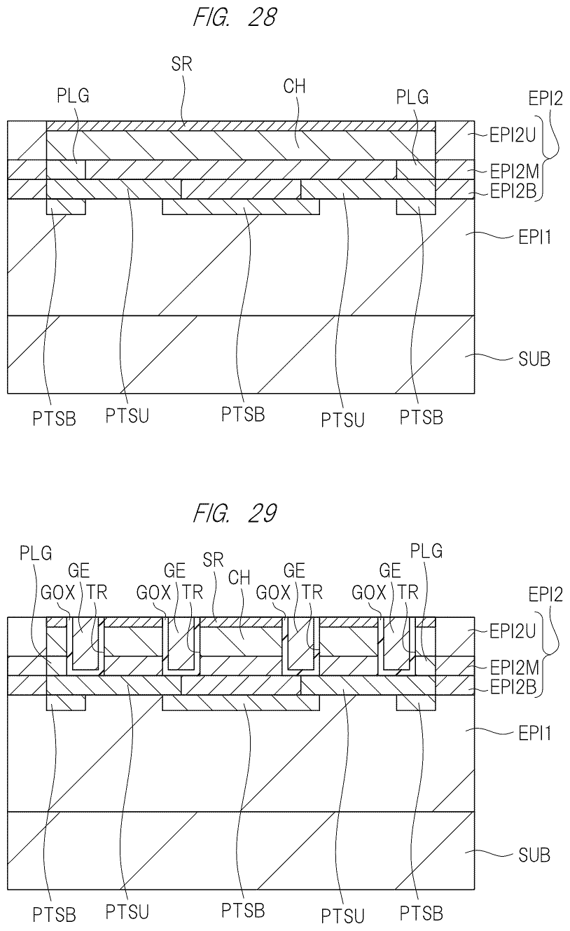

Next, as illustrated in FIG. 29, trenches TR are formed by using photolithography and etching. Then, after forming a gate insulating film GOX on the inner walls of the trenches TR, gate electrodes GE are formed in the trenches TR via the gate insulating film GOX. Accordingly, the punch-through stopper layer PTSB is formed in the epitaxial layer EPI1. The lower epitaxial layer EPI2B, the punch-through stopper layer PTSU, the middle epitaxial layer EPI2M, the p-type plugs PLG, the upper epitaxial layer EPI2U, the channel layer CH, the source region SR, the trenches TR, the gate insulating film GOX, and the gate electrodes GE can be formed.

The punch-through stopper layer is configured of the punch-through stopper layer PTSB formed in the epitaxial layer EPI1 and the punch-through stopper layer PTSU formed in the lower epitaxial layer EPI2B.

The source region SR and the channel layer CH are electrically connected to each other and supplied with the ground potential. That is, the ground potential is supplied to each of the source region SR and the channel layer CH. The punch-through stopper layer PTSU is electrically connected to the channel layer CH to which the ground potential is supplied via the p-type plugs PLG. Therefore, the ground potential is supplied to the punch-through stopper layer PTSU. The punch-through stopper layer PTSB is connected to the punch-through stopper layer PTSU. Therefore, the ground potential is also supplied to the punch-through stopper layer PTSB. This makes it possible to implement the configuration in which the ground potential is supplied to the punch-through stopper layer PTSB and the punch-through stopper layer PTSU.

The advantage of manufacturing such a structure D is as follows. That is, the punch-through stopper layer is configured of the punch-through stopper layer PTSB formed in the epitaxial layer EPI1 and the punch-through stopper layer PTSU formed in the lower epitaxial layer EPI2B. This improves the degree of freedom in the arrangement of the punch-through stopper layer to achieve both a shielding effect of efficiently alleviating electric field concentration in the vicinity of the bottom of a trench and a reduction in the on-resistance by making it easier to secure the current path for the MOSFET (improvement in the electrical characteristics of the MOSFET).

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
an epitaxial layer of a first conductivity type made of a wide band gap semiconductor material having a band gap larger than that of silicon;
a plurality of trenches formed in the epitaxial layer;
a plurality of gate electrodes formed in the plurality of trenches via a gate insulating film; and
a punch-through stopper layer formed in the epitaxial layer and formed deeper than the plurality of trenches, and having a second conductivity type opposite to the first conductivity type,
wherein, in plan view, the punch-through stopper layer includes a first portion and a second portion adjacent to each other,
wherein, in plan view, the first portion and the second portion each have a first pattern having a same planar shape,
wherein the first pattern is configured of one or more sub-patterns, and
wherein, in plan view, the one or more sub-patterns configuring the first pattern each partially overlap with any of the plurality of gate electrodes.

2. The semiconductor device according to claim 1,
wherein the planar shape of the punch-through stopper layer forms a geometric pattern composed of repetitions of the first pattern as a unit pattern.

3. The semiconductor device according to claim 1,
wherein the first pattern is configured of the one or more sub-patterns including any of straight lines, rectangles, circles, and curves.

4. The semiconductor device according to claim 1,
wherein, the first pattern is configured of a pattern capable of tessellating a plane, and
wherein, the pattern capable of tessellating a plane is a pattern that uses a finite number of planar figures, where the planar figures do not overlap and can fill a plane without any gaps.

5. The semiconductor device according to claim 4,
wherein the first pattern is configured of one or more sub-patterns, and
wherein the plurality of sub-patterns, is configured of a combination of a plurality of single figures.

6. The semiconductor device according to claim 4,
wherein the first pattern is configured of one or more sub-patterns, and
wherein the plurality of sub-patterns, is configured of a combination of a plurality types of figures.

7. The semiconductor device according to claim 1,
wherein each of the plurality of gate electrodes extends in a first direction, and
wherein the one or more sub-patterns configuring the first pattern each extend in a second direction that intersects with the first direction.

8. The semiconductor device according to claim 1,
wherein the first portion and the second portion each have a second pattern having a ring shape surrounding the first pattern in plan view.

9. The semiconductor device according to claim 8,
wherein the first pattern is connected to the second pattern.

10. The semiconductor device according to claim 9,
wherein the first pattern and the second pattern are supplied with a ground potential.

11. The semiconductor device according to claim 10,
wherein the epitaxial layer includes a first epitaxial layer of the first conductivity type and a second epitaxial layer of the first conductivity type formed on the first epitaxial layer,
wherein the semiconductor device includes
a punch-through stopper layer formed in the first epitaxial layer,
a plug formed in the second epitaxial layer, connected to the punch-through stopper layer, and filled with a semiconductor material of the second conductivity type,
a channel layer of the second conductivity type formed in the second epitaxial layer and electrically connected to the plug, and
a source region of the first conductivity type formed in the second epitaxial layer and on the channel layer, and
wherein the source region is electrically connected to the channel layer.

12. The semiconductor device according to claim 11,
wherein the second epitaxial layer includes a second lower epitaxial layer of the first conductivity type, a second middle epitaxial layer of the first conductivity type formed on the second lower epitaxial layer, and a second upper epitaxial layer of the first conductivity type formed on the second middle epitaxial layer,
wherein the plug is configured of a lower plug formed in the second lower epitaxial layer, and a middle plug formed in the second middle epitaxial layer and connected to the lower plug,
wherein the channel layer is formed in the second upper epitaxial layer, and
wherein the source layer is formed in the second upper epitaxial layer.

13. The semiconductor device according to claim 10,
wherein the epitaxial layer includes a first epitaxial layer of the first conductivity type and a second epitaxial layer of the first conductivity type formed on the first epitaxial layer,
wherein the semiconductor device includes
a punch-through stopper layer formed in the first epitaxial layer,
a plug formed in the second epitaxial layer, connected to the punch-through stopper layer, and filled with a semiconductor material of the second conductivity type,
a dummy electrode contained in the plug and does not function as a gate electrode,
a channel layer of the second conductivity type formed in the second epitaxial layer and electrically connected to the plug, and
a source region of the first conductivity type formed in the second epitaxial layer and on the channel layer, and
wherein the source region is electrically connected to the channel layer.

14. The semiconductor device according to claim 10,
wherein the epitaxial layer includes a first epitaxial layer of the first conductivity type and a second epitaxial layer of the first conductivity type formed on the first epitaxial layer,
wherein the punch-through stopper layer is configured of a first punch-through stopper layer formed in the first epitaxial layer, and a second punch-through stopper layer formed in the second epitaxial layer and connected to the first punch-through stopper layer.

15. The semiconductor device according to claim 1,
wherein the wide band gap semiconductor material is silicon carbide.
